(19) United States
(12) Patent Application Publication
(10) Pub. No.: US 2010/0003600 A1
(43) Pub. Date: Jan. 7, 2010

(54) SOLID-STATE STRUCTURE COMPRISING A BATTERY AND A VARIABLE RESISTOR OF WHICH THE RESISTANCE IS CONTROLLED BY VARIATION OF THE CONCENTRATION OF ACTIVE SPECIES IN ELECTRODES OF THE BATTERY

(75) Inventors: Rogier Adrianus Henrica Niessen, Eindhoven (NL); Petrus Henricus Laurentius Notten, Eindhoven (NL); Johannes Hubertus Gerardus Op Het Veld, Eindhoven (NL); Remco Henricus Wilhelmus Pijnenburg, Hoogeloon (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/518,330

(22) PCT Filed: Dec. 7, 2007
(86) PCT No.: PCT/IB2007/054962

§ 371 Date: Jun. 9, 2009

(30) Foreign Application Priority Data
Dec. 14, 2006 (EP) 06126165.7

(51) Int. Cl. H01M 4/02; H01L 21/02

(52) U.S. Cl. 429/211; 438/381; 257/E21.004

(57) ABSTRACT

Presently, many variations of possible integrated resistors are utilized in IC design. However, depending on the electrical circuit it is often desirable that a resistor does not have a constant value, but rather that such a resistor has a variable controllable value. The invention relates to a solid-state variable resistor. The invention also relates to an electronic device, comprising such a solid-state variable resistor. The invention further relates to a method for producing a solid-state variable resistor.

### FIELD OF THE INVENTION

The invention relates to a solid-state variable resistor. The invention also relates to an electronic device, comprising such a solid-state variable resistor. The invention further relates to a method for producing a solid-state variable resistor.

### BACKGROUND OF THE INVENTION

Presently, many variations of possible integrated resistors are utilized in IC design. However, depending on the electrical circuit it is often desirable that a resistor does not have a constant value, but rather that such a resistor has a variable controllable value. Currently, MOSFETs can be used as tunable or variable resistors. In these devices the gate voltage can tune the resistance value across the semiconductor channel. In most MOSFETs it is hard to accurately tune the exact resistance of the semi-conductor channel. Very often only a low (“on” state) and a high (“off” state) resistance state are employed. This is directly related to the fact that below the threshold voltage of the MOSFET the semi-conducting channel does not conduct any current (high resistance), whereas above the threshold voltage the resistance drops exponentially.

Currently different types of MOSFETs are manufactured. Among these are power MOSFETs. Although they are widely used, the voltage needed to operate these devices is quite high. Generally, for state-of-the-art power MOSFETs, a gate voltage of well over 10 V is needed to be able to be sure that the MOSFET is fully switched “on” (low resistance). This feature does not only require a high control voltage but also leads to a substantial dissipation of power within the MOSFET structure leading to a high temperature.

Novel concepts (3D integration) of all-solid-state rechargeable thin film Li-ion batteries were previously described in patent WO2005/027245A2. Generally, these power sources can be used for many applications such as implantables, sensors and autonomous devices. However, it has appeared to the inventors that these battery stacks can also be advantageously used in the manufacture of a fully tunable resistor. Herein the tuning of the resistance is based on the electrochemical insertion/deinsertion of active species in a host material.

### SUMMARY OF THE INVENTION

In line with this realisation the invention provides a solid-state variable resistor, comprising a first battery electrode layer deposited on a substrate, a solid electrolyte layer deposited on said first battery electrode layer, a second battery electrode layer deposited on the solid electrolyte layer and two resistor contacts being both in contact with one of the electrode layers.

Herein the resistor is formed by the electrode material present between the two resistor contacts. In this material a path between the contacts is formed of which the resistance varies with the concentration or the density of the active species in the storage material of which the electrode is formed.

However, the tunable resistor does provide a number of advantages over existing (power) MOSFETS used as variable resistors. Firstly, as the tuning of the resistance is based on the electrochemical insertion/deinsertion of active species in a material, its operating voltage is dependent on the chosen intercalation materials and can be as low as 0.5 to 1 V.

Secondly, as the electrochemical doping of the material that serves as the conducting pathway is fully reversible, almost no power is dissipated (as heat) in tuning the resistance thereof. This will result in the fact that that is less chance of a thermal breakdown and even high temperature operation of the device might be possible.

Thirdly, as the doping of the conducting pathway can be done in a very accurate way, both potentiostatically and galvanostatically, the resistance of the material can be tuned very precisely. This can be achieved over several orders of magnitude depending on the intercalation material that is chosen, ranging from a metallic-like state (low resistance) to a semi-conducting state (high resistance). Consequently the use of the tunable resistor disclosed in this document, allows a wide range of resistance values.

Preferably the resistor contacts are in contact with the anodic electrode layer. In this embodiment the anodic electrode layer in fact functions as a resistor of which the resistance value depends on the concentration of the active species in said anodic electrode. The actual concentration can be regulated, just as the concentration of the active species in the cathodic electrode layer. However the materials suitable for use in the anodic electrode are more advantageous in reaching a high variation in electric resistance with a transfer of a small amount of charge to or from the electrode than the materials generally used in cathodic electrodes. Hence it could be more attractive to use the anodic electrode.

It is however also possible to use that the resistor contacts are in contact with the cathodic electrode layer. This embodiment may be advantageous in some situations, like situations wherein an opposite polarity of the control signal is easier available.

According to a preferred embodiment, the first battery layer is an anodic battery layer and the second layer is a cathodic battery layer. Herein the anodic electrode layer is deposited directly on the substrate, making it easier to provide and connect the resistor contacts.

According to another preferred embodiment the first battery layer is a cathodic battery layer and the second layer is an anodic battery layer. These features could commonly be advantageous from a viewpoint of production technology.

The effects of the charge and discharge process in the electrode take place in a direction substantially perpendicular to the separating plane between the electrode layer and the electrolyte layer. To make the resistance between the resistor contacts as homogeneous as possible it is advantageous if over the path between the resistor contacts the concentration or density of the active species is substantially homogeneous. This can be achieved if the contacts are separated by a path extending substantially parallel to the plane separating the electrode layer from the electrolyte layer.

Preferably the resistor contacts are deposited adjacent to the electrode layer with which they are in contact. In this embodiment, the resistor contacts will often be embedded within the volume of the electrolyte layer separating both electrode layers.

It is however also possible to locate the resistor contacts within the volume of the electrode layer itself. Consequently according to a preferred embodiment the electrode layer to which the resistor contacts are connected comprises a current collector layer wherein the resistor contacts are separated from said current collector layer by a special dielectric or insulating layer. Herein the dielectric or insulating layer avoids electric shunt paths via the current collector.

According to a preferred embodiment the resistor contacts are both strip shaped and extend mutually parallel, leading to a simple yet effective embodiment, suitable for relatively high resistance values.

Another preferred embodiment provides the feature that the resistor contacts are both comb shaped and are mutually interleaved. This leads to a generally shorter and wider path through which the current flows and hence to lower resistance values.

Preferably the resistor contacts are made of at least one of the following materials: Al, Ni, Pt, Au, Ag, Cu, Ta, Ti, TaN, and TiN. These materials and possible other materials which are inert relative to the active species within the potential range prevailing in the electrode, appear to be suitable materials to make the resistor contacts of. Further platinum is especially suitable as it is not prone to oxidation during the deposition of the layers of the battery.

According to yet another preferred embodiment, the active species is formed by lithium (Li) and the storage material is a lithium compound, like LiₓV₂O₅, LiₓWO₃, LiₓSi, LiₓBi, or LiₓSb. It has appeared to the inventors that these combinations of materials lead to a large difference in resistance with a limited variation of concentration and hence to a good control of the resistance with an input signal requiring only limited power.

Instead of lithium (Li) other materials can be used as active species, as there are storage materials of which the properties vary substantially with the concentration of the active species. This seems to be the case in particular with hydrogen (H) as active species.

When hydrogen is used as active species, the storage material is preferably formed by Mg-based hydrides, such as HₓMg_{y}M_{(1-y)}, with M=Sc, Ti, V, Cr, Gd, Sm, Y; HₓMg₂Ni or HₓRE, with RE=Rare Earths, as these combination in particular leads to a large variation in resistance with a small variation in concentration of active species in the storage material.

By patterning or structuring one, and preferably both, electrodes of the resistor according to the invention, a three-dimensional surface area, and hence an increased surface area per footprint of the electrode(s), and an increased contact surface per volume between the at least one electrode and the electrolytic stack is obtained. This increase of the contact surface(s) leads to an improved effectiveness of the dependency of the resistance from the charge condition.

It is preferred that at least one surface of at least one electrode is substantially patterned, and more preferably that the applied pattern is provided with one or more cavities, in particular pillars, trenches, slits, or holes, which particular cavities can be applied in a relatively accurate manner. In this manner the increased performance of the controllable resistor can also be predetermined in a relatively accurate manner.

In this context it is noted that a surface of the substrate onto which the stack is deposited may be either substantially flat or may be patterned (by curving the substrate and/or providing the substrate with trenches, holes and/or pillars) to facilitate generating a three-dimensional oriented resistor.

Preferably, each electrode comprises a current collector. By means of the current collectors the resistor structure can easily be connected to an electronic device. Preferably, the current collectors are made of at least one of the following materials: Al, Ni, Pt, Au, Ag, Cu, Ta, Ti, TaN, and TiN. Other kinds of current collectors, such as, preferably doped, semiconductor materials such as e.g. Si, GaAs, InP may also be applied to act as current collector.

The solid-state resistor preferably comprises at least one barrier layer being deposited between the substrate and at least one electrode, which barrier layer is adapted to at least substantially preclude diffusion of active species of the cell into said substrate. In this manner the substrate and the electrochemical cell will be separated chemically, as a result of which the performance of the electrochemical cell and hence of the capacitor can be maintained relatively long-lastingly. In case a lithium ion based cell is applied, the barrier layer is preferably made of at least one of the following materials: Ta, TaN, Ti, and TiN. It may be clear that also other suitable materials may be used to act as barrier layer.

In a preferred embodiment preferably a substrate is applied, which is ideally suitable to be subjected to a surface treatment to pattern the substrate, which may facilitate patterning of the electrode(s). The substrate is more preferably made of at least one of the following materials: C, Si, Sn, Ti, Ge, Al, Cu, Ta, and Pb. A combination of these materials may also be used to form the substrate(s). Preferably, n-type or p-type doped Si or Ge is used as substrate, or a doped Si-related and/or Ge-related compound, like SiGe or SiGeC. Beside relatively rigid materials, also substantially flexible materials, such as e.g. foils like Kapton® foil, may be used for the manufacturing of the substrate. It may be clear that also other suitable materials may be used as a substrate material.

The invention also provides an electrical device comprising a controllable resistor as claimed in any of the preceding claims. Also in such an embodiment the fruitful effects of the invention appear very well.

The invention also provides a method for producing a solid-state variable resistor, comprising a first battery electrode layer deposited on a substrate, a solid electrolyte layer deposited on said first battery electrode layer, a second battery electrode layer deposited on the solid electrolyte layer, two resistor contacts being both in contact with one of the electrode layers, wherein the method comprises the steps of deposition of the first electrode layer on the substrate, deposition of a solid electrolyte layer on the first electrode layer, deposition of a second electrode layer on the solid electrolyte layer, deposition of a pair of electrodes, wherein the electrodes are deposited either preceding or following the deposition of one of the electrode layers. Through this method the resistor according to the invention is produced in a simple and effective way. An important feature of the resistor of the invention is formed by the presence of the resistor contacts, required to form the resistor circuit. These contacts can be deposited after the deposition of the electrode layer through which the path between the contacts extends. In this situation the electrodes are within the volume of the electrolyte layer in contact with the electrode layer.

However it is also possible that the contacts are deposited before the electrode layer is deposited. In that case contact between a current collector layer and the contacts should be avoided. Consequently a preferred method comprises the steps of deposition of an anodic electrode layer on the substrate, deposition of a pair of contacts on the anodic layer, deposition of a solid electrolyte layer on the anodic layer and on the contacts and deposition of a cathodic electrode layer on said electrolyte layer.

### BRIEF DESCRIPTION OF THE DRAWINGS

Subsequently the present invention will be elucidated with the help of the following non-limitative drawings, showing:

FIG. 1: a cross sectional view of a structure of a solid-state battery, on which the principle of the invention is based;

FIG. 2a: a cross sectional view of the structure of a first embodiment of the resistor according to the invention;

FIG. 2b: a sectional view extending, of the resistor depicted in FIG. 2a, perpendicular to the view of FIG. 2a;

FIG. 3a: a cross sectional view of the structure of a second embodiment of the resistor according to the invention;

FIG. 3b: a sectional view extending, of the resistor depicted in FIG. 3a, perpendicular to the view of FIG. 3a; and

FIG. 4: a cross sectional view of the structure of a third embodiment of the resistor according to the invention.

### DETAILED DESCRIPTION OF THE EMBODIMENTS

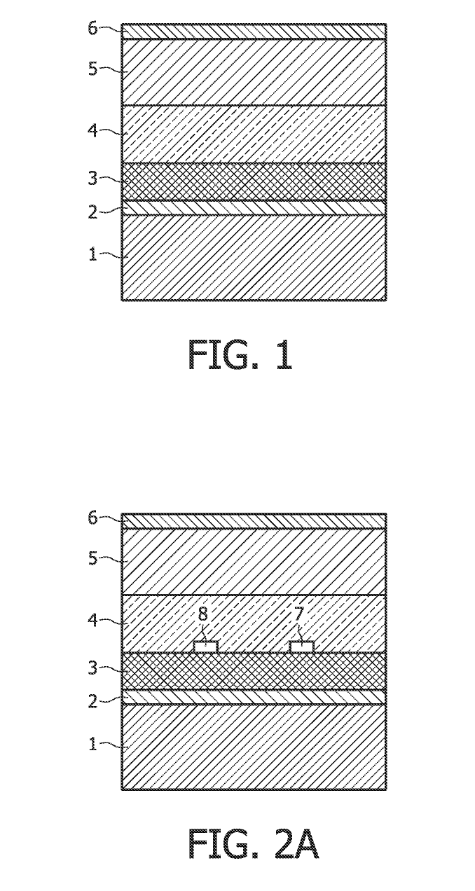

FIG. 1 shows a cross sectional view of the all solid-state thin film battery disclosed in WO-A-2005/027245. Using the deposition and integration technology described in this document, a stack can be manufactured that can be use to make an electrochemically tunable resistor. This stack comprises a substrate 1, onto which a current collector 2 has been deposited. An anode layer 3 has been deposited on the current collector layer 2 and on the anode layer 3 an electrolyte layer 4 has been deposited. On the electrolyte layer 4 a cathode layer 5 and thereon a current collector layer 6 has been deposited. The stack structure thus obtained is described in WO-A-2005/027245.

In FIG. 1 the battery is depicted in the discharged state. In this situation the anode is completely de-lithiated (and the cathode fully lithiated). The resistance of the anode can be measured and will be roughly equal to the resistance of amorphous elemental silicon.

In its charged state the anode is fully lithiated and the cathode will be deficient in lithium. This time the resistance of the anode layer 3 will be roughly that of the Li₄Si material. Inherent to the fully reversible nature of the rechargeable battery operation, the exact amount or concentration of active species (in this case lithium atoms) can be tuned within the anode material. Consequently the resistance of the anode layer 3 can be accurately tuned.

In order to be able to use the anode layer similar to the conducting path between the source and drain in a MOSFET, these resistor contacts have to be added to the stack.

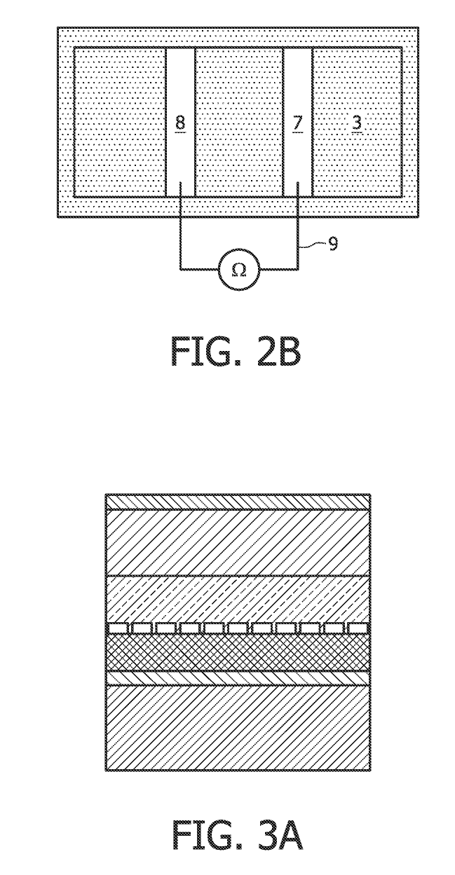

In FIG. 2a a similar stack structure is shown wherein two resistor contacts 7, 8 are deposited on top of the anode layer 3. For the sake of clarity a top view of just the anode layer 3 with the resistor contacts 7, 8 is depicted in FIG. 2b. The resistor contacts 7, 8 are preferably made of platinum (Pt) as this material is completely inert towards lithium intercalation at the operating potential used. By contacting these two resistor contacts the resistance of the (lithiated) anode layer 3 between the contacts 7, 8 can be utilized as a resistor in an electrical circuit 9.

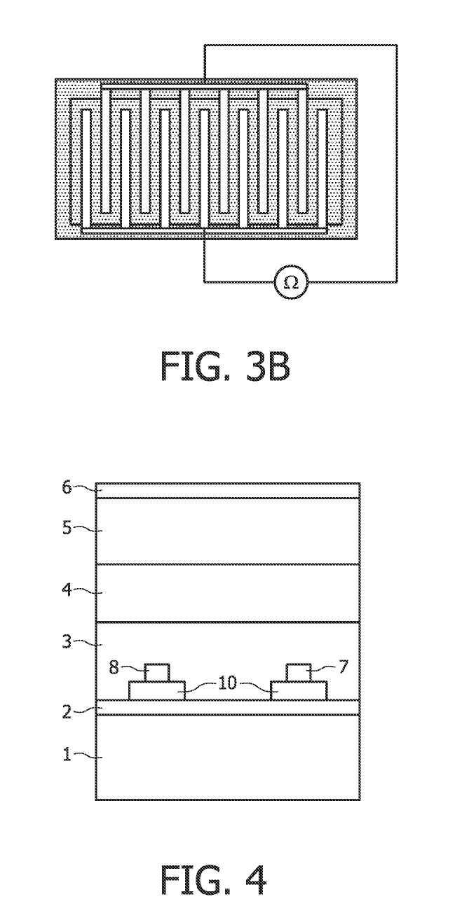

FIGS. 3a and 3b show a similar embodiment, but wherein the resistor contacts 7, 8 have an alternative shape. Both resistor contacts 7, 8 have the shape of a comb of which the teeth are interlocked. These teeth should be as thin as possible as not to interrupt or obstruct the movement of lithium from the anode to the cathode (or the reverse) during battery operation. The effect of this shape is that the length of the path between the resistor contacts 7,8 is shorter than in the preceding embodiment and that its width is substantially larger. Both effects cooperate to obtain a smaller resistance between the electrodes, which can be advantageous in some applications of the invention.

In both embodiments discussed above, the resistor contacts 7, 8 are located on the anode layer 3. It is however also possible that the resistor contacts 7, 8 are located within the anode layer 3, as shown by FIG. 4. The resistor contacts 7, 8 can however not be directly applied on the current collector layer 2 as this current collector layer which is made of electrical conducting material would short circuit the resistor contacts 7,8. To avoid this disadvantageous effect, an insulating or dielectric layer 10 has been deposited under both resistor contacts 7, 8. This structure can be applied with contact shapes as disclosed both in FIGS. 2 and 3.

By wisely choosing the anode and cathode material of which the completely battery stack is made, the amount of charge and/or power that needs to be transferred in order to change the concentration and hence the resistance in the anode layer can be kept to a minimum. This means that the operating voltage for such a tunable resistor can be as low as 0.5-1 V. Moreover, as the battery operation is fully reversible, an infinitesimal amount of power is dissipated.

Strictly speaking, as the concentration of active species (lithium in this case) of course also changes in the cathode, the resistance of this layer can also be used as a controllable resistor. Needless to say one should opt for materials in which a small concentration difference results in a large resistance difference. Known materials of which these material properties vary a lot are for example for lithium systems: LiₓV₂O₅, LiₓWO₃, LiₓSi, or LiₓSb.

However, this is certainly not restricted to solely lithium systems (lithium doping), but can easily be extended to materials of which the materials properties dramatically change upon hydrogen intercalation. Prime examples are Mg-based hydrides such as HₓMₓMg_{y}M_{(1-y)} with M=Sc, Ti, V, Cr, Gd, Sm, Y, HₓMg₂Ni, HₓRE with RE=rare earths. Most of these materials are able to switch from a metallic state at low hydrogen content to semi-conducting state at high hydrogen content.

It is emphasized that the embodiments described above, relate to battery structures wherein the anode is deposited on the substrate, but it is equally well possible that the cathodic electrode is deposited initially, leading to a reverse stack.

Finally, it should be noted that changing the resistance in the device disclosed in this document is not as fast as in a MOSFET due to the fact that active species have to be introduced or removed from an active layer by means of (electro)chemical reactions. This requires a certain amount of time.

This invention discloses the manufacturing of an electrochemically tunable resistor. These integrated tunable resistors can be used as smart electronic components in IC design aimed at replacing several analog components.

1. Solid-state variable resistor, comprising:
a first battery electrode layer deposited on a substrate;
a solid electrolyte layer deposited on said first battery electrode layer;
a second battery electrode layer deposited on the solid electrolyte layer; and
two resistor contacts being both in contact with one of the electrode layers.

2. Solid-state variable resistor as claimed in claim 1, wherein the resistor contacts are in contact with the anodic electrode layer.

3. Solid-state variable resistor as claimed in claim 1, wherein the resistor contacts are in contact with the cathodic electrode layer.

4. Solid-state variable resistor as claimed in claim 1, wherein the first battery layer is an anodic battery layer and the second layer is a cathodic battery layer.

5. Solid-state variable resistor as claimed in claim 1, wherein the first battery layer is a cathodic battery layer and the second layer is an anodic battery layer.

6. Solid-state variable resistor as claimed in claim 1, wherein the contacts are separated by a path extending substantially parallel to the plane separating the electrode layer from the electrolyte layer.

7. Solid-state variable resistor as claimed in claim 1, wherein the resistor contacts are deposited adjacent to the electrode layer with which it is in contact.

8. Solid-state variable resistor as claimed in claim 1, wherein the electrode layer with which the contacts are connected comprises a current collector layer and wherein the contacts are separated from said current collector layer by a dielectric layer.

9. Solid-state variable resistor as claimed in claim 1, wherein the resistor contacts are both strip shaped and extend mutually parallel.

10. Solid-state variable resistor as claimed in claim 1, wherein the resistor contacts are both comb shaped and are mutually interleaved.

11. Solid-state variable resistor as claimed in claim 1, wherein the contacts are made of at least one of the following materials: Al, Ni, Pt, Au, Ag, Cu, Ta, Ti, TaN, and TiN.

12. Solid-state variable resistor as claimed in claim 1, wherein the active species is formed by lithium (Li).

13. Solid-state variable resistor as claimed in claim 12, wherein at least one electrode material comprises a lithium compound, like LiₓV₂O₅, LiₓWO₃, LiₓSi, LiₓBi or LiₓSb.

14. Solid-state variable resistor as claimed in claim 1, wherein the active species is formed by hydrogen (H).

15. Solid-state variable resistor as claimed in claim 14, wherein at least one electrode material is formed by Mg-based hydrides, such as HₓMg_{y}M_{(1-y)}, with M=Sc, Ti, V, Cr, Gd, Sm, Y; HₓMg₂Ni or HₓRE, with RE=Rare Earths.

16. Solid-state variable resistor as claimed in claim 1, wherein at least one electrode is provided with at least one patterned surface.

17. Solid-state variable resistor as claimed in claim 1, wherein the at least one patterned surface of the at least one electrode is provided with multiple cavities.

18. Solid-state variable resistor as claimed in claim 17, wherein at least a part of the cavities form pillars, trenches, slits, or holes.

19. Solid-state resistor as claimed in claim 8, wherein the at least one current collector is made of at least one of the following materials: Al, Ni, Pt, Au, Ag, Cu, Ta, Ti, TaN, and TiN.

20. Solid-state resistor as claimed in claim 1, wherein the energy source further comprises at least one electron-conductive barrier layer being deposited between the substrate and at least one electrode, which barrier layer is adapted to at least substantially preclude diffusion of active species of the cell into said substrate.

21. Solid-state resistor as claimed in claim 20, wherein the at least one barrier layer is made of at least one of the following materials: Ta, TaN, Ti, and TiN.

22. Solid-state resistor according to claim 1, wherein the substrate comprises Si and/or Ge.

23. Solid-state resistor according to claim 1, wherein the substrate is made of a flexible material, like Kapton® or a metal foil.

24. Electronic device, comprising at least one resistor according to claim 1.

25. Method for producing a solid-state variable resistor comprising:
a first battery electrode layer deposited on a substrate;
a solid electrolyte layer deposited on said first battery electrode layer;
a second battery electrode layer deposited on the solid electrolyte layer;
two resistor contacts being both in contact with one of the electrode layers,
the method comprising the following steps:
deposition of the first electrode layer on the substrate;
deposition of a solid electrolyte layer on the first electrode layer;
deposition of a second electrode layer on the solid electrolyte layer;
deposition of a pair of electrodes,
wherein the resistor contacts are deposited either preceding or following the deposition of one of the electrode layers.
